(19) United States
(12) Patent Application Publication
(10) Pub. No.: US 2023/0084785 A1
(43) Pub. Date: Mar. 16, 2023

(54) Cleaning System

(71) Applicant: Daifuku Co., Ltd., Osaka-shi (JP)

(72) Inventors: Koichi Hagiwara, Komaki-shi (JP); Tsuyoshi Uemura, Hinocho (JP)

(21) Appl. No.: 17/945,548

(22) Filed: Sep. 15, 2022

(30) Foreign Application Priority Data
Sep. 16, 2021 (JP) 2021-150941

(51) Int. Cl. A47L 9/28; A47L 9/00

(52) U.S. Cl. CPC A47L 9/2852; A47L 9/0063; A47L 9/2805; A47L 2201/04; A47L 2201/06; A47L 2201/024; A47L 2201/028; B61B 3/02

(57) ABSTRACT

A cleaning system includes a cleaning vehicle that cleans a predetermined travel route, a maintenance facility provided at a specified position on the travel route and performs maintenance on the cleaning vehicle, and a control device that controls them. The control device executes interruption and maintenance control in response to a state of the cleaning vehicle satisfying a predetermined maintenance condition during execution of the cleaning by the cleaning vehicle. The interruption and maintenance control includes first control for interrupting the cleaning performed by the cleaning vehicle, causing the cleaning vehicle to move to the specified position, and causing the maintenance facility to perform the maintenance on the cleaning vehicle, and second control for causing, after the first control, the cleaning vehicle to move to an interruption position at which the cleaning was interrupted, and causing the cleaning vehicle to resume the cleaning from the interruption position.

### CROSS-REFERENCE TO RELATED APPLICATION

This application claims priority to Japanese Patent Application No. 2021-150941 filed Sep. 16, 2021, the disclosure of which is hereby incorporated by reference in its entirety.

### BACKGROUND OF THE INVENTION

### Field of the Invention

The present invention relates to a cleaning system that includes a cleaning vehicle that travels along a predetermined travel route and cleans the travel route, and a maintenance facility provided at a specified position on the travel route.

### Description of the Related Art

An example of such a cleaning system is disclosed in Japanese Laid-Open Patent Publication No. 2013-605 (hereinafter referred to as “Patent Document 1”). In the cleaning system of Patent Document 1, a cleaning vehicle (W) cleans a travel route (L) by suctioning dust that has accumulated along the travel route (L). Note that the reference numerals in parentheses in the description of the related art are those used Patent Document 1.

In the cleaning system of Patent Document 1, if it is determined that maintenance needs to be performed on the cleaning vehicle (W) while the cleaning vehicle (W) is performing cleaning, the cleaning vehicle (W) is moved to a maintenance facility, and maintenance (e.g., the removal of dust suctioned by the cleaning vehicle) is performed on the cleaning vehicle.

In this way, in the cleaning system of Patent Document 1, if it is determined that maintenance needs to be performed on the cleaning vehicle (W) while the cleaning vehicle (W) is performing cleaning, maintenance is performed on the cleaning vehicle (W) even if cleaning has not been completed. When the cleaning vehicle (W) resumes the cleaning after maintenance is complete, there have been cases where the cleaning becomes inefficient, such as the case where a region that was already cleaned before the start of the maintenance is cleaned again. If a worker manually sets the position where the cleaning vehicle (W) resumes cleaning after maintenance is complete, it is possible to avoid the case where cleaned regions overlap each other, but this has a disadvantage of an increased burden on the worker.

### SUMMARY OF THE INVENTION

In view of the foregoing, there is desire for the realization of a cleaning system in which cleaning can be performed automatically and efficiently by a cleaning vehicle.

Additionally, in view of the foregoing, a characteristic configuration of a cleaning system includes:
at least one cleaning vehicle configured to travel along a predetermined travel route and clean the travel route;
a maintenance facility provided at a specified position on the travel route and configured to perform maintenance on the cleaning vehicle; and
a control device configured to control the at least one cleaning vehicle and the maintenance facility,
wherein the control device executes interruption and maintenance control in response to a state of the at least one cleaning vehicle satisfying at least one predetermined maintenance condition during execution of the cleaning by the cleaning vehicle, and
the interruption and maintenance control includes
   a first control of interrupting the cleaning performed by the at least one cleaning vehicle, causing the at least one cleaning vehicle to move to the specified position, and causing the maintenance facility to perform the maintenance on the at least one cleaning vehicle, and
   a second control of causing, after the first control, the at least one cleaning vehicle to move to an interruption position at which the cleaning was interrupted, and causing the at least one cleaning vehicle to resume the cleaning from the interruption position.

According to this characteristic configuration, in the interruption and maintenance control, after the first control is executed to interrupt cleaning performed by the cleaning vehicle and cause the maintenance facility to perform maintenance on the cleaning vehicle, the second control is executed to resume cleaning from the position where cleaning was interrupted. Accordingly, in the case where the cleaning vehicle resumes cleaning after the completion of maintenance, it is possible to avoid the case where a region that was cleaned before the start of maintenance is cleaned again. Also, there is no need for a worker or the like to manually set the position at which the cleaning vehicle resumes cleaning after the completion of maintenance. Accordingly, the cleaning performed by the cleaning vehicle can be performed automatically and efficiently.

Also, according to the above characteristic configuration, by setting the maintenance condition for executing the interruption and maintenance control, it is possible to automatically perform maintenance on the cleaning vehicle at an appropriate time. Accordingly, the cleaning vehicle can be kept in a favorable condition.

### BRIEF DESCRIPTION OF THE DRAWINGS

FIG. 1 is a schematic diagram showing an overall configuration of an article transport facility provided with a cleaning system according to an embodiment.

FIG. 2 is a side view of a cleaning vehicle and a transport vehicle.

FIG. 3 is a control block diagram of the article transport facility provided with the cleaning system according to the embodiment.

FIG. 4 shows first control in interruption and maintenance control.

FIG. 5 shows second control in interruption and maintenance control.

FIG. 6 is a diagram showing an example of the setting of cleaning zones and the association of cleaning vehicles with cleaning zones.

FIG. 7 is a diagram showing an example of the setting of conditions for starting the washing of a cleaning vehicle.

FIG. 8 is a flowchart showing an example of control processing performed by a control device.

FIG. 9 is a flowchart showing an example of interruption and maintenance control.

### DESCRIPTION OF THE INVENTION

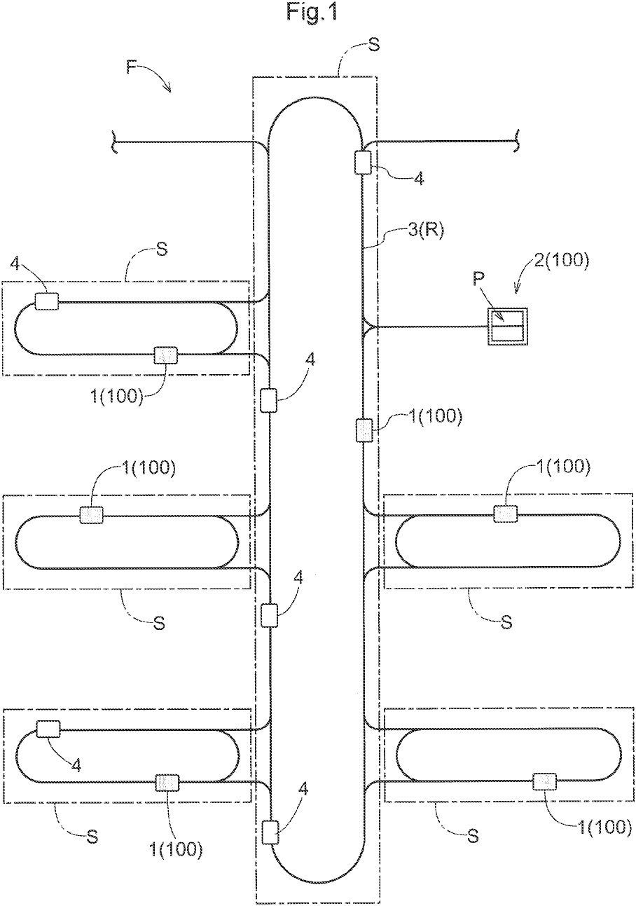

A cleaning system 100 according to an embodiment will be described below with reference to the drawings. As shown in FIG. 1, in the present embodiment, the cleaning system 100 is provided in an article transport facility F.

First, the article transport facility F will be described. The article transport facility F includes rails 3 and transport vehicles 4.

The rails 3 constitute a travel route R for the transport vehicles 4. In the present embodiment, the rails 3 are supported so as to be suspended from the ceiling of the article transport facility F.

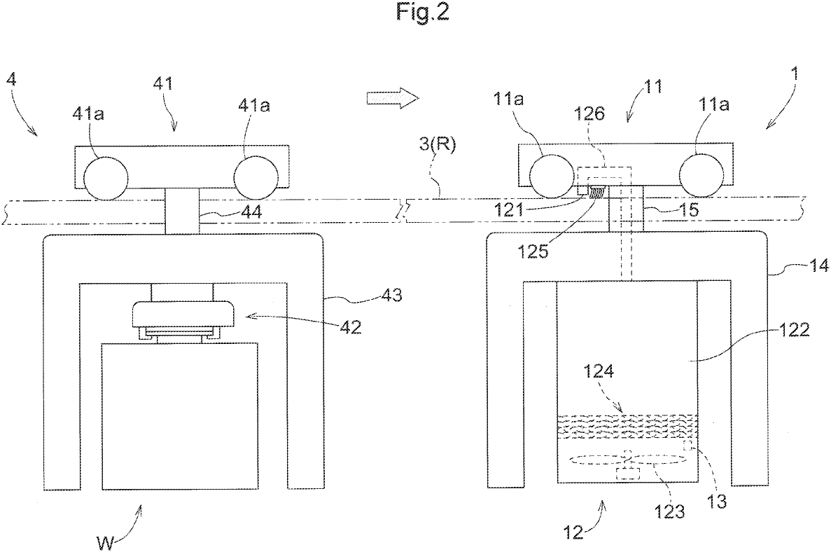

The transport vehicles 4 are configured to travel along the travel route R. In the present embodiment, a plurality of transport vehicles 4 are provided. The transport vehicles 4 are configured to transport articles W (see FIG. 2) to one of a plurality of transport target locations (not shown) arranged along the travel route R. The articles W are each a FOUP (Front Opening Unified Pod) that houses a plurality of semiconductor wafers, for example. In this case, the transport vehicles 4 transport the articles W to transport target locations such as a processing device for processing semiconductor wafers or a storehouse for temporary storage.

As shown in FIG. 2, in the present embodiment, the transport vehicles 4 each include a first travel section 41, a transfer section 42, and a first cover 43.

The first travel section 41 includes a plurality of first wheels 41a that roll on the rails 3. In the present embodiment, at least one of the first wheels 41a is rotated by driving force from a travel motor (not shown) so as to roll on the rails 3, and thus the remaining first wheels 41a also move on the rails 3. In this way, the first travel section 41 travels along the travel route R configured by the rails 3.

The transfer section 42 transfers an article W to and from a transport target location. Although not described in detail here, the transfer section 42 includes a holding section for holding the article W, and an elevating section for lifting and lowering the holding section relative to the first travel section 41, for example. The transfer section 42 also includes a horizontal movement section that moves the holding section horizontally relative to the first travel section 41, and a turn section that rotates the holding section relative to the first travel section 41 about a rotation axis extending in the vertical direction. Note that the transfer section 42 need only have a configuration necessary for transferring an article W to and from a transport target location, and is not limited to having the above configuration.

The first cover 43 is formed to cover the article W held by the transfer section 42. In the present embodiment, the first cover 43 is formed so as to cover the article W from above and both sides in the traveling direction of the first travel section 41 (left-right direction in FIG. 2) when the article W is being held by the holding section while the holding section is located at the highest position in the range of movement by the elevating section. Also, in the present embodiment, the first cover 43 is coupled to the first travel section 41 via a first coupling section 44 so as to be suspended from the first travel section 41.

Next, the cleaning system 100 will be described. As shown in FIG. 1, the cleaning system 100 includes cleaning vehicles 1 and a maintenance facility 2.

The cleaning vehicles 1 travel along a predetermined travel route R. The cleaning vehicles 1 clean the travel route R. In the present embodiment, the travel route R that is cleaned by the cleaning vehicles 1 is the travel route R along which the transport vehicles 4 travel. For this reason, the cleaning vehicles 1 and the transport vehicles 4 are configured to travel on the same rails 3 that form the travel route R. In the present embodiment, the cleaning vehicles 1 clean dust that has accumulated on the rails 3. Such dust appears due to the operation of components in the article transport facility F, such as due to the wearing of the first wheels 41a when the transport vehicles 4 travel on the rails 3.

In the present embodiment, a plurality of cleaning vehicles 1 are provided. Also, a plurality of cleaning zones S are set along the travel route R. Each of the cleaning vehicles 1 is associated with at least one cleaning zone S, and performs cleaning in the associated cleaning zone S. In the illustrated example, the travel route R includes a plurality of loop routes, and the cleaning zones S are set in one-to-one correspondence with the loop routes.

The maintenance facility 2 is configured to perform maintenance on the cleaning vehicles 1. The maintenance facility 2 is provided at a specified position P along the travel route R. In the present embodiment, the specified position P is set on a route different from the route along which articles W are transported by the transport vehicles 4 in the travel route R. Accordingly, it is possible to avoid a situation in which a cleaning vehicle 1 and a transport vehicle 4 that have stopped at the specified position P interfere with a transport vehicle 4 that is traveling to transport an article W.

As shown in FIG. 2, in the present embodiment, each of the cleaning vehicles 1 includes a second travel section 11, a cleaning section 12, a dust amount detection section 13, and a second cover 14.

The second travel section 11 includes a plurality of second wheels 11a that roll on the rails 3. In the present embodiment, at least one of the second wheels 11a is rotated by driving force from a travel motor (not shown) so as to roll on the rails 3, and thus the remaining second wheels 11a also move on the rails 3. In this way, the second travel section 11 travels along the travel route R configured by the rails 3.

The cleaning section 12 includes a suction nozzle 121, a storage member 122, a fan 123, and a filter 124.

The suction nozzle 121 is a nozzle for suctioning dust that has accumulated on the rails 3. The suction nozzle 121 is arranged so as to face a dust accumulation location on the rails 3 (here, the upper surfaces of the rails 3). The suction nozzle 121 is fixed to the second travel section 11 so as to move together with the second travel section 11.

In the present embodiment, a brush member 125 is provided at a position adjacent to the suction nozzle 121 on the downstream side thereof in the traveling direction of the second travel section 11 (see the bold arrow in FIG. 2). The brush member 125 is a group of bristles (e.g., synthetic fibers, carbon fibers, or metal fibers). The brush member 125 is arranged so as to come into contact with the dust accumulation location on the rails 3 (here, the upper surfaces of the rails 3). The brush member 125 is fixed to the second travel section 11 so as to move together with the second travel section 11. For this reason, dust that has accumulated on the rails 3 is removed from the rails 3 by the brush member 125 as the second travel section 11 travels along the rails 3. Dust removed from the rails 3 by the brush member 125 is suctioned by the suction nozzle 121.

The storage member 122 is configured to store dust suctioned by suction nozzle 121. In the present embodiment, the internal space of the storage member 122 and the suction nozzle 121 are in communication with each other via a pipe 126.

The fan 123 and the filter 124 are arranged in the internal space of the storage member 122. The fan 123 generates an airflow for allowing the suction nozzle 121 to suction dust that has accumulated on the rails 3. In the present embodiment, the airflow generated by the fan 123 flows through the suction nozzle 121, the pipe 126, and the internal space of the storage member 122 in this order. The filter 124 captures dust suctioned by the suction nozzle 121. In the present embodiment, the filter 124 is arranged upstream of the fan 123 in the direction of the airflow generated by the fan 123.

The dust amount detection section 13 is configured to detect the amount of dust collected by the cleaning section 12. In the present embodiment, the dust amount detection section 13 detects the amount of dust captured by the filter 124. In this example, the dust amount detection section 13 includes a pressure sensor that detects the pressure in the internal space of the storage member 122. Here, as the amount of dust captured by the filter 124 increases, it becomes more difficult for the airflow generated by fan 123 to pass through the filter 124, and thus the pressure difference between the spaces on opposite sides of filter 124 in the internal space of the storage member 122 increases. The dust amount detection section 13 detects the amount of dust captured by the filter 124 by detecting the pressure difference described above. In the example shown in FIG. 2, the dust amount detection section 13 is arranged in the internal space of the storage member 122, at a location downstream of the filter 124 in the flowing direction of the airflow generated by the fan 123. For this reason, the dust amount detection section 13 detects the amount of dust captured by the filter 124 by detecting a decrease in the pressure at a location downstream of the filter 124 in the internal space of the storage member 122. Note that any of various known types of sensors can be used as the pressure sensor included in the dust amount detection section 13.

The second cover 14 is formed so as to cover at least a portion of the cleaning section 12. In the present embodiment, the second cover 14 is formed so as to cover the storage member 122 of the cleaning section 12 from above and both sides in the traveling direction of the second travel section 11 (the left-right direction in FIG. 2). Also, in the present embodiment, the second cover 14 is coupled to the second travel section 11 via a second coupling section 15 so as to be suspended from the second travel section 11. Note that in the present embodiment, portions of the pipe 126 are arranged inside the second cover 14 and inside the second connecting portion 15.

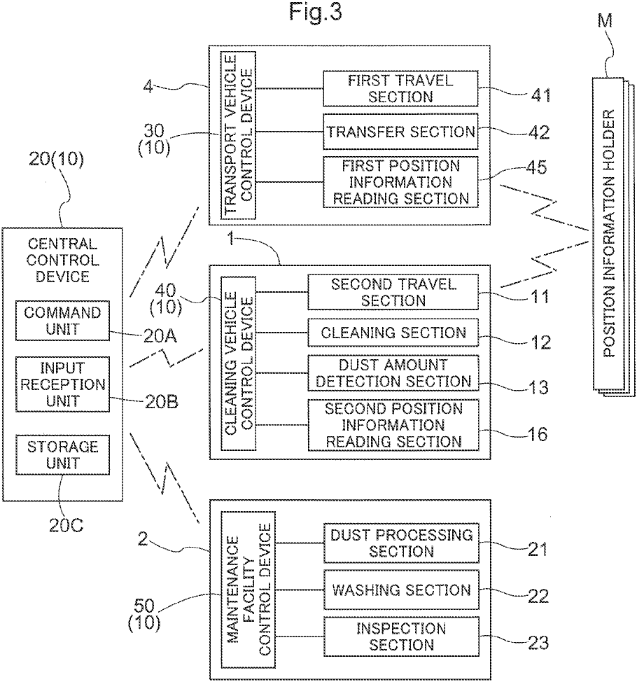

As shown in FIG. 3, in the present embodiment, the maintenance facility 2 includes a dust processing section 21 for processing dust collected by the cleaning vehicle 1, a washing section 22 for washing the cleaning vehicle 1, and an inspection section 23 for inspecting the cleaning vehicle 1. For this reason, in the present embodiment, maintenance includes the processing of dust collected by the cleaning vehicle 1, the washing of the cleaning vehicle 1, and the inspection of the cleaning vehicle 1. In the present embodiment, the washing section 22 is configured to wash the transport vehicles 4 in addition to the cleaning vehicles 1. Also, the inspection section 23 is configured to inspect the transport vehicles 4 in addition to the cleaning vehicles 1.

Note that in the present embodiment, the replacement of the filter 124 of the cleaning vehicle 1 corresponds to the processing of dust collected by the cleaning vehicle 1, which is included in the maintenance described above. In other words, in the present embodiment, maintenance performed on the cleaning vehicles 1 includes an operation in which the filter 124 that has captured the dust suctioned by the suction nozzle 121 is replaced with a new filter 124 by the dust processing section 21 of the maintenance facility 2. The replacement of the filter 124 may be performed automatically if a device for performing such replacement is provided in the dust processing section 21, or may be performed manually by a worker.

As shown in FIG. 3, in the present embodiment, each of the transport vehicles 4 includes a first position information reading section 45. Also, each of the cleaning vehicles 1 includes a second position information reading section 16. The first position information reading section 45 and the second position information reading section 16 can read position information that is held by position information holders M that are provided at a plurality of locations on or near the rails 3. The position information holders M each hold position information that corresponds to the installation position of the position information holder M. Note that the position information holders M can be configured using a barcode or a wireless tag, for example. If the position information holders M are configured by a barcode, the first position information reading section 45 and the second position information reading section 16 may be configured as a barcode reader. On the other hand, if the position information holders M are configured by a wireless tag, the first position information reading section 45 and the second position information reading section 16 may be configured as a tag reader.

As shown in FIG. 3, the cleaning system 100 includes a control device 10 that controls the cleaning vehicles 1 and the maintenance facility 2. In the present embodiment, the control device 10 includes a central control device 20, a transport vehicle control device 30 that controls the transport vehicles 4, a cleaning vehicle control device 40 that controls the cleaning vehicles 1, and a maintenance facility control device 50 that controls the maintenance facility 2.

The central control device 20 includes a command unit 20A, an input reception unit 20B, and a storage unit 20C. The command unit 20A outputs commands to the transport vehicle control device 30, the cleaning vehicle control device 40, and the maintenance facility control device 50 to control the devices that such control devices are in charge of. The input reception unit 20B receives input operations performed by a worker. The input reception unit 20B can be configured using a touch panel display, a keyboard, or a mouse, for example. Various information necessary for controlling the cleaning system 100 is stored in the storage unit 20C. In the present embodiment, as will be described later, information indicating interruption positions Pi, which are the positions at which cleaning vehicles 1 interrupted cleaning, is stored in the storage unit 20C.

The transport vehicle control device 30 is provided in each of the transport vehicles 4. The transport vehicle control device 30 controls operations of the first travel section 41 and the transfer section 42 of the transport vehicle 4 based on commands from the central control device 20. Also, based on position information that is held by the position information holders M and was read by the first position information reading section 45, the transport vehicle control device 30 acquires the position on the travel route R at which the transport vehicle 4 that includes the transport vehicle control device 30 is located. Information indicating the position of the transport vehicle 4 acquired in this way is transmitted from the transport vehicle control device 30 to the central control device 20.

The cleaning vehicle control device 40 is provided in each of the cleaning vehicles 1. The cleaning vehicle control device 40 controls operations of the second travel section 11 and the cleaning section 12 of the cleaning vehicle 1 based on commands from the central control device 20. Furthermore, the cleaning vehicle control device 40 acquires information indicating the amount of dust captured by the filter 124 based on a detection signal from the dust amount detection section 13. Also, based on position information that is held by the position information holders M and was read by the second position information reading section 16, the cleaning vehicle control device 40 acquires the position on the travel route R at which the cleaning vehicle 1 that includes the cleaning vehicle control device 40 is located. Information indicating the position of the cleaning vehicle 1 acquired in this way is transmitted from the cleaning vehicle control device 40 to the central control device 20. Information indicating the amount of dust that was captured may also be transmitted from the cleaning vehicle control device 40 to the central control device 20.

The maintenance facility control device 50 is provided in the maintenance facility 2. The maintenance facility control device 50 controls operations of the dust processing section 21, the washing section 22, and the inspection section 23 based on commands from the central control device 20.

The control device 10 executes interruption and maintenance control if the state of a cleaning vehicle 1 satisfies a predetermined maintenance condition while the cleaning vehicle 1 is performing cleaning. The interruption and maintenance control includes first control and second control that is executed after the first control.

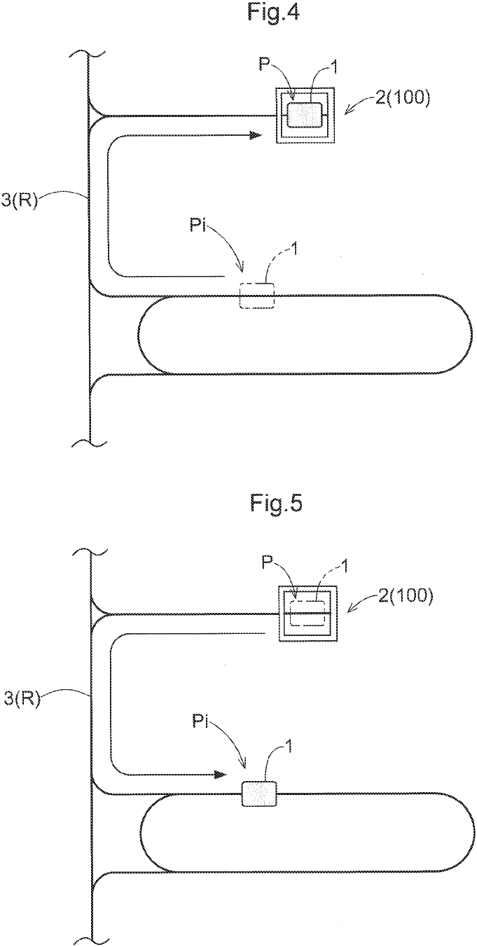

As shown in FIG. 4, in the first control, the control device 10 interrupts the cleaning performed by the cleaning vehicle 1. The control device 10 then causes the cleaning vehicle 1 to move from an interruption position Pi, which is the position where the cleaning was interrupted, to a specified position P. After that, the control device 10 causes the maintenance facility 2 to perform maintenance on the cleaning vehicle 1 that has moved to the specified position P. Note that in the present embodiment, the interruption position Pi is calculated based on position information that is held by the position information holder M and was read by the second position information reading section 16 provided in the cleaning vehicle 1. Information indicating the interruption position Pi calculated in this way is stored in the storage unit 20C. More specifically, if there are a plurality of cleaning vehicles 1, an identification code for identifying the cleaning vehicle 1 whose cleaning was interrupted is stored in association with information indicating the interruption position Pi at which the cleaning performed by that cleaning vehicle 1 was interrupted.

As shown in FIG. 5, in the second control, the control device 10 causes the cleaning vehicle 1 on which maintenance was performed to move from the specified position P to the interruption position Pi. The control device 10 then causes the cleaning vehicle 1 that moved to the interruption position Pi to resume cleaning from the interruption position Pi. At this time, the control device 10 reads information indicating the interruption position Pi of the cleaning vehicle 1 from the storage unit 20C, and outputs, to the cleaning vehicle 1, a travel command that includes the interruption position Pi as the destination.

The movement of the cleaning vehicle 1 between the interruption position Pi and the specified position P is set such that the movement route between the interruption position Pi and the specified position P is as short as possible while also giving consideration to the traveling direction of the cleaning vehicle 1, interference with a transport vehicle 4, congestion on the travel route R, and the like.

In the present embodiment, maintenance conditions for executing the interruption and maintenance control include at least either a first condition, which is that cleaning in a cleaning zone S set on the travel route R is complete, or a second condition, which is that the amount of cleaning time that has elapsed since completion of previous maintenance exceeds a predetermined threshold value TH. In this example, the maintenance conditions also include that the amount of dust captured by the filter 124 is greater than a predetermined dust amount threshold value. Note that the dust amount threshold value is determined by experimentation or the like, while giving consideration to the size of the space where the pressure sensor of the dust amount detection section 13 measures the pressure, the suction force of the airflow generated by the fan 123, the type of the filter 124, and the like.

Also, in the present embodiment, the control device 10 associates a different cleaning vehicle 1 with each of the cleaning zones S, and causes the cleaning vehicles 1 to perform cleaning in the corresponding cleaning zones S. In the present embodiment, the worker uses the input reception unit 20B to set the cleaning zones S that are to be cleaned, and associate cleaning vehicles 1 with the cleaning zones S.

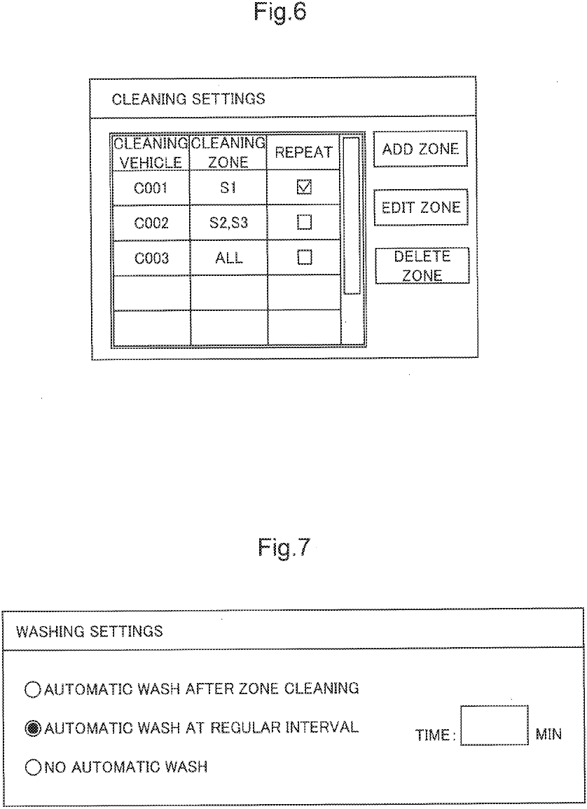

FIG. 6 shows a method using a user interface provided by the input reception unit 20B as an example of a method for setting the cleaning zones S that are to be cleaned and associating cleaning vehicles 1 with the cleaning zones S. In the example shown in FIG. 6, by selecting a cleaning vehicle 1 that has not been associated with a cleaning zone S and then pressing an “add zone” button via an input device, the worker can set a cleaning zone S that is to be cleaned and associate the selected cleaning vehicle 1 with that cleaning zone S. Also, by selecting a cleaning vehicle 1 that is already associated with a cleaning zone S and then pressing an “edit zone” button via the input device, the worker can edit the cleaning zone S that is associated with that cleaning vehicle 1. Note that each cleaning vehicle 1 can be associated with one or more cleaning zones S, or can be associated with the entire range of the travel route R. For example, in FIG. 6, the cleaning zone S indicated by “S1” is associated with the cleaning vehicle 1 indicated by “C001”. Also, the cleaning vehicle 1 indicated by “C002” is associated with the cleaning zone S indicated by “S2” and the cleaning zone S indicated by “S3”. Furthermore, the cleaning vehicle 1 indicated by “C003” is associated with the entire range of the travel route R indicated by “ALL”.

Note that in this example, when setting a cleaning zone S, the worker can input a desired zone on the travel route R via the input reception unit 20B, or make a selection from a plurality of preset cleaning zones on the travel route R. As described above, in the present embodiment, the input reception unit 20B of the control device 10 has a function as a “zone setting reception unit” that can receive input of a zone on the travel route R, and can receive a selection from a plurality of preset zones on the travel route R. A candidate condition received by the input reception unit 20B is set as a cleaning zone S that is to be cleaned.

Also, in the example shown in FIG. 6, by selecting a cleaning vehicle 1 that has already been associated with a cleaning zone S and then pressing a “delete zone” button via the input device, the worker can delete the cleaning zone S that is associated with that cleaning vehicle 1.

Also, by checking a “repeat” check box via the input device, the worker can cause the cleaning vehicle 1 that corresponds to that check box to repeatedly perform cleaning in the associated cleaning zone S. In this way, in the present embodiment, the control device 10 can execute repetitive cleaning control for causing a cleaning vehicle 1 to repeatedly perform cleaning in a cleaning zone S set on the travel route R.

FIG. 7 shows a method using a user interface provided by the input reception unit 20B as an example of a method for setting a condition for starting the washing of a cleaning vehicle 1, which is a maintenance operation performed by the maintenance facility 2. In the example shown in FIG. 7, if the worker selects an “automatic wash after zone cleaning” radio button via the input device, then after a cleaning vehicle 1 completes cleaning in the corresponding cleaning zone S, that cleaning vehicle 1 automatically moves to the maintenance facility 2 and is washed by the washing section 22. If the “automatic wash after zone cleaning” radio button is selected, the first condition is selected as a maintenance condition. Also, if the worker selects an “automatic wash at regular interval” radio button and inputs a desired time (in units of minutes) via the input device, then when the amount of cleaning time that has elapsed since completion of previous maintenance reaches the input time, the cleaning vehicle 1 moves to the maintenance facility 2 and is washed by the washing section 22. If the “automatic wash at regular interval” radio button is selected, the second condition is selected as a maintenance condition. The input time corresponds to the threshold value TH. Also, if the worker selects a “no automatic wash” radio button via the input device, the cleaning vehicle 1 does not automatically move to the maintenance facility 2 for washing. If the “no automatic wash” radio button is selected, neither the first condition nor the second condition is selected as a maintenance condition.

In this way, in the present embodiment, the input reception unit 20B of the control device 10 has a function as a “selection reception unit” that receives selection of a candidate condition to be applied which candidate condition is selected from among a plurality of preset candidate conditions including the first condition and the second condition. The candidate condition received by this input reception unit 20B is set as a maintenance condition.

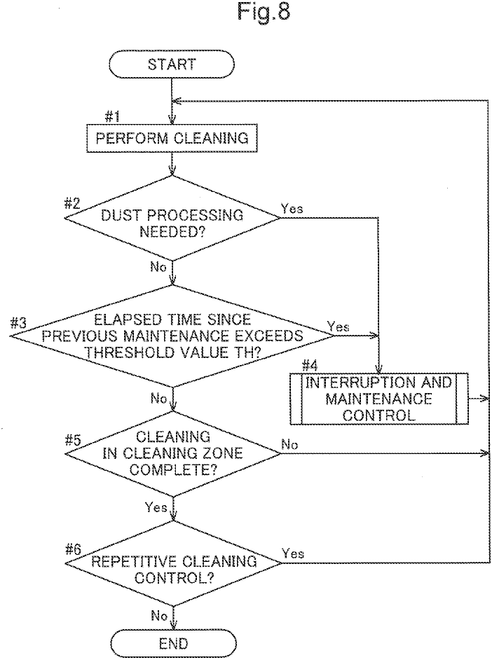

FIG. 8 shows a flowchart showing an example of control processing performed by the control device 10. In the example shown in FIG. 8, it is assumed that the “automatic wash at regular interval” radio button in FIG. 7 has been selected, that is to say, the second condition has been selected as a maintenance condition. Also, in this example, regardless of the selected maintenance condition, when the amount of dust captured by the filter 124 exceeds the predetermined dust amount threshold value, the cleaning vehicle 1 is caused to move to the maintenance facility 2 for dust processing.

As shown in FIG. 8, first, the control device 10 causes the cleaning vehicle 1 to perform cleaning in the corresponding cleaning zone S (step #1).

Next, the control device 10 determines whether or not the dust collected by the cleaning vehicle 1 needs to be processed (step #2). Here, if the amount of dust captured by the filter 124, which is calculated based on the detection signal from the dust amount detection section 13, exceeds the predetermined dust amount threshold value, the control device 10 determines that the dust collected by the cleaning vehicle 1 needs to be processed. On the other hand, if the amount of dust captured by the filter 124, which is calculated based on the detection signal from the dust amount detection section 13, is less than or equal to the dust amount threshold value, the control device 10 determines that the dust collected by the cleaning vehicle 1 does not need to be processed.

In the case of determining that the dust collected by the cleaning vehicle 1 needs to be processed (step #2: Yes), the control device 10 executes interruption and maintenance control (step #4).

On the other hand, in the case of determining that the dust collected by the cleaning vehicle 1 does not need to be processed (step #2: No), the control device 10 determines whether or not the amount of cleaning time that has elapsed since completion of previous maintenance exceeds the predetermined threshold value TH (step #3). In other words, the control device 10 determines whether or not the second condition, which was selected as a maintenance condition, is satisfied.

If the amount of cleaning time that has elapsed since completion of previous maintenance exceeds the threshold value TH (step #3: Yes), the control device 10 executes interruption and maintenance control (step #4).

On the other hand, if the amount of cleaning time that has elapsed since completion of previous maintenance does not exceed the threshold value TH (step #3: No), the control device 10 determines whether or not the cleaning vehicle 1 has completed cleaning in the cleaning zone S (step #5).

If the cleaning vehicle 1 has not completed cleaning in the cleaning zone S (step #5: No), the control device 10 returns to step #1 and causes the cleaning vehicle 1 to continue performing cleaning in the cleaning zone S. On the other hand, if the cleaning vehicle 1 has completed cleaning in the cleaning zone S (step #5: Yes), the control device 10 determines whether or not to execute repetitive cleaning control to cause the cleaning vehicle 1 to repeatedly perform cleaning in the cleaning zone S (step #6). Here, the control device 10 determines whether or not the execution of repetitive cleaning control has been set, specifically, whether or not the “repeat” check box in FIG. 6 is checked.

In the case where repetitive cleaning control is to be executed (step #6: Yes), the control device 10 returns to step #1 and causes the cleaning vehicle 1 to perform cleaning in the cleaning zone S again. On the other hand, if repetitive cleaning control is not to be executed (step #6: No), the control device 10 ends this control processing.

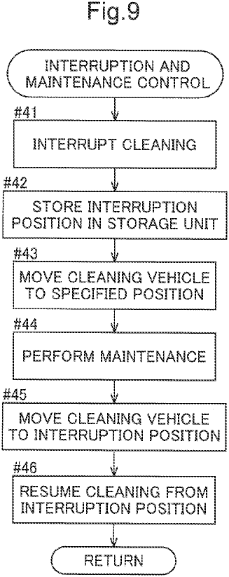

FIG. 9 shows a flowchart showing an example of interruption and maintenance control. As shown in FIG. 9, in the interruption and maintenance control, first, the control device 10 interrupts the cleaning of the cleaning zone S performed by the cleaning vehicle 1 (step #41). Next, the control device 10 stores, in the storage unit 20C, the interruption position Pi indicating the position where the cleaning was interrupted (step #42). The control device 10 then causes the cleaning vehicle 1 to move from the interruption position Pi to the specified position P (step #43). Subsequently, the control device 10 causes the maintenance facility 2 to perform maintenance on the cleaning vehicle 1 that moved to the specified position P (step #44). Then, when the maintenance performed on the cleaning vehicle 1 is complete, the control device 10 causes the cleaning vehicle 1 to move from the specified position P to the interruption position Pi based on the information indicating the interruption position Pi of the cleaning vehicle 1 stored in the storage unit 20C (step #45). When the cleaning vehicle 1 reaches the interruption position Pi, the control device 10 causes the cleaning vehicle 1 to resume cleaning from the interruption position Pi (step #46). Note that the above-described steps #41 to #44 correspond to the first control in the interruption and maintenance control. Moreover, the above-described steps #45 and #46 correspond to the second control in the interruption and maintenance control.

As described above, the above flowchart shows control in a state in which the “automatic wash at regular interval” radio button in FIG. 7 has been selected, that is to say, in a state in which the second condition has been selected as a maintenance condition. If the “automatic wash after zone cleaning” radio button in FIG. 7 has been selected, that is to say, if the first condition has been selected as a maintenance condition, step #3 described above is not executed, and the interruption and maintenance control is executed when it is determined in step #5 that the cleaning of the cleaning zone S by the cleaning vehicle 1 is complete.

Other Embodiments
(1) In the above embodiment, the setting of a condition for starting the washing of a cleaning vehicle 1, which is a maintenance operation (see FIG. 7), is described by way of example of a configuration in which it is possible to select either the first condition, which is that cleaning in a cleaning zone S is complete, or the second condition, which is that the amount of cleaning time that has elapsed since completion of previous maintenance exceeds the predetermined threshold value TH. However, the present invention is not limited to such a configuration, and as another example, a configuration is possible in which either the first condition or the second condition can be selected as a condition for starting the processing of dust collected by the cleaning vehicle 1, which is another maintenance operation. In this case, it is not necessary to employ a configuration for executing the interruption and maintenance control if the amount of dust captured by the filter 124 is greater than the predetermined dust amount threshold value (see FIG. 8). Alternatively, a configuration may be employed in which, in addition to the first condition and the second condition, there is a third condition that the amount of dust captured by the filter 124 is greater than the predetermined dust amount threshold value, and a selectable “dust box full” radio button corresponding to the third condition is displayed in the user interface (see FIG. 7) provided by the input reception unit 20B. In this case, any condition among the first, second, and third conditions can be selected as a condition for starting the processing of the dust collected by the cleaning vehicle 1.
(2) In the above embodiment, an example is described in which the threshold value TH can be set in units of minutes (see FIG. 7). However, the present invention is not limited to such a configuration, and as another example, the threshold value TH can be set in units of hours or days.
(3) In the above embodiment, an example is described in which it is possible to select whether or not to execute repetitive cleaning control for causing the cleaning vehicle 1 to repeatedly perform cleaning in the cleaning zone S (see FIG. 6). However, the present invention is not limited to such a configuration, and a configuration is possible in which repetitive cleaning control is always executed, and a configuration is possible in which repetitive cleaning control is not executed.
(4) In the above embodiment, an example is described in which the dust amount detection section 13 detects the amount of dust captured by the filter 124 by detecting the pressure in the internal space of the storage member 122. However, the present invention is not limited to such a configuration, and as another example, a configuration is possible in which the dust amount detection section 13 measures the elapsed time since the suction nozzle 121 started suctioning dust along the travel route R, and detects the amount of dust captured by the filter 124 based on the elapsed time. Also, a configuration is possible in which the dust amount detection section 13 uses a transmissive optical sensor to measure the amount of light transmitted through the filter 124, and detects the amount of dust captured by the filter 124 based on the measured amount of light.
(5) In the above embodiment, an example is described in which the cleaning system 100 is applied to the article transport facility F that includes the rails 3 suspended from the ceiling. However, the present invention is not limited to such a configuration, and the article transport facility F to which the cleaning system 100 is applied may include rails 3 provided on the floor surface, for example.
(6) In the above embodiment, an example is described in which the cleaning vehicle 1 is configured to clean dust that has accumulated on the rails 3, but the present invention is not limited to this. For example, in some cases, a power supply line for supplying power to the transport vehicles 4 may be arranged along the travel route R. In this case, the cleaning vehicles 1 may be configured to clean dust adhering to the power supply line. Alternatively, the cleaning vehicles 1 may be configured to clean both dust that has accumulated on the rails 3 and dust adhering to the power supply line. Note that in the case where the cleaning vehicle 1 cleans dust adhering to the power supply line, it is preferable that the suction nozzle 121 is provided so as to face the power supply line. In other words, the suction nozzle 121 is provided so as to face the dust accumulation location on the travel route R. Similarly, the brush member 125 is also provided so as to come into contact with the dust accumulation location on the travel route R.
(7) In the above embodiment, an example is described regarding the case where the setting of the cleaning zones S on the travel route R is fixed, but the present invention is not limited to this, and a configuration is possible in which the setting of the cleaning zones S can be changed as appropriate. For example, it is preferable that a worker can freely change settings using a control terminal or the like.
(8) In the above embodiment, an example is described in which information indicating the interruption position Pi, which is the position at which cleaning performed by the cleaning vehicle 1 was interrupted, is stored in the storage unit 20C provided in the central control device 20, but the present invention is not limited to this. Information indicating the interruption position Pi may be stored in a storage unit included in the cleaning vehicle control device 40, for example.
(9) In the above embodiment, an example is described in which the filter 124 is replaced in the dust processing section 21 of the maintenance facility 2. However, the present invention is not limited to this, and as another example, the replacement of the filter 124 may be performed at a location different from the dust processing section 21 in the maintenance facility 2. Alternatively, the replacement of the filter 124 may be performed in a facility different from the maintenance facility 2.
(10) Note that the configurations disclosed in the above embodiments can also be applied in combination with configurations disclosed in other embodiments as long as no contradiction arises. Regarding other configurations as well, the embodiments disclosed in this specification are merely examples in all respects. Accordingly, various modifications can be made as appropriate without departing from the scope of the present disclosure.

### Overview of Embodiments

Below, an overview of the cleaning system described above will be described.

A cleaning system according to an aspect includes:
at least one cleaning vehicle configured to travel along a predetermined travel route and clean the travel route;
a maintenance facility provided at a specified position on the travel route and configured to perform maintenance on the at least one cleaning vehicle; and
a control device configured to control the at least one cleaning vehicle and the maintenance facility,
wherein the control device executes interruption and maintenance control in response to a state of the at least one cleaning vehicle satisfying at least one predetermined maintenance condition during execution of the cleaning by the cleaning vehicle, and
the interruption and maintenance control includes
   a first control of interrupting the cleaning performed by the at least one cleaning vehicle, causing the at least one cleaning vehicle to move to the specified position, and causing the maintenance facility to perform the maintenance on the at least one cleaning vehicle, and
   a second control of causing, after the first control, the at least one cleaning vehicle to move to an interruption position at which the cleaning was interrupted, and causing the at least one cleaning vehicle to resume the cleaning from the interruption position.

According to this configuration, in the interruption and maintenance control, after the first control is executed to interrupt cleaning performed by the cleaning vehicle and cause the maintenance facility to perform maintenance on the cleaning vehicle, the second control is executed to resume cleaning from the position where the cleaning was interrupted. Accordingly, in the case where the cleaning vehicle resumes cleaning after the completion of maintenance, it is possible to avoid the case where a region that was cleaned before the start of maintenance is cleaned again. Also, there is no need for a worker or the like to manually set the position at which the cleaning vehicle resumes cleaning after the completion of maintenance. Accordingly, the cleaning performed by the cleaning vehicle can be performed automatically and efficiently.

Also, according to the above configuration, by setting the maintenance condition for executing the interruption and maintenance control, it is possible to automatically perform maintenance on the cleaning vehicle at an appropriate time. Accordingly, the cleaning vehicle can be kept in a favorable condition.

Here, it is preferable that the at least one maintenance condition includes at least one of a first condition that the cleaning in a cleaning zone set along the travel route is complete, and a second condition that an amount of cleaning time that has elapsed after completion of previous maintenance exceeds a predetermined threshold value.

According to this configuration, the maintenance condition for executing the interruption and maintenance control includes at least either the first condition or the second condition. Accordingly, maintenance can be automatically performed on the cleaning vehicle at an appropriate time.

Also, it is preferable that the control device includes a selection reception unit configured to receive selection of a candidate condition to be applied from among a plurality of preset candidate conditions including the first condition and the second condition, and the control device sets the candidate condition received by the selection reception unit as the maintenance condition.

According to this configuration, the worker or the like can select, via the selection reception unit, one of a plurality of candidate conditions including the first condition and the second condition as a maintenance condition for executing the interruption and maintenance control. Accordingly, maintenance of the cleaning vehicle can be automatically performed according to the maintenance condition that was set by the worker in accordance with the use condition of the cleaning vehicle and at the request of the worker.

Also, it is preferable that the control device includes a zone setting reception unit configured to receive input of a zone along the travel route and receive a selection made from among a plurality of preset zones along the travel route, and the control device sets the zone received by the zone setting reception unit as a cleaning zone to be cleaned.

According to this configuration, the worker or the like can select a desired zone along the travel route as a cleaning zone via the zone setting reception unit, and can also select one of a plurality of preset zones along the travel route and set the selected zone as the cleaning zone. Accordingly, the cleaning zone can be set easily and with a high degree of freedom.

Also, it is preferable that the at least one cleaning vehicle includes a plurality of cleaning vehicles, a plurality of the cleaning zones are set along the travel route, and the control device associates a different cleaning vehicle with each of the cleaning zones, and causes each of the cleaning vehicles to perform the cleaning in the associated cleaning zone.

According to this configuration, the cleaning of a plurality of cleaning zones set along the travel route can be performed in parallel by a plurality of cleaning vehicles. Accordingly, cleaning can be performed more efficiently with use of a plurality of cleaning vehicles.

Also, it is preferable that the control device is configured to execute repetitive cleaning control that causes the cleaning vehicle to repeatedly perform the cleaning in the cleaning zone set along the travel route.

According to this configuration, even if the dust removal rate is not high when the cleaning vehicle performs cleaning one time, the amount of dust that accumulates in the cleaning zone can be kept low by repeatedly performing cleaning in the cleaning zone set along the travel route. Accordingly, the cleaning performed by the cleaning vehicle can be performed automatically and efficiently.

### INDUSTRIAL APPLICABILITY

The technology according to the present disclosure is applicable to a cleaning system that includes a cleaning vehicle that travels along a predetermined travel route and cleans the travel route, and also includes a maintenance facility provided at a specified position on the travel route.

What is claimed is:

1. A cleaning system comprising:
at least one cleaning vehicle configured to travel along a predetermined travel route and clean the travel route;
a maintenance facility provided at a specified position on the travel route and configured to perform maintenance on the at least one cleaning vehicle; and
a control device configured to control the at least one cleaning vehicle and the maintenance facility,
wherein the control device executes interruption and maintenance control in response to a state of the at least one cleaning vehicle satisfying at least one predetermined maintenance condition during execution of the cleaning by the cleaning vehicle, and
wherein the interruption and maintenance control comprises:
a first control of interrupting the cleaning performed by the at least one cleaning vehicle, causing the at least one cleaning vehicle to move to the specified position, and causing the maintenance facility to perform the maintenance on the at least one cleaning vehicle, and
a second control of causing, after the first control, the at least one cleaning vehicle to move to an interruption position at which the cleaning was interrupted, and causing the at least one cleaning vehicle to resume the cleaning from the interruption position.

2. The cleaning system according to claim 1,
wherein the at least one maintenance condition includes at least one of a first condition that the cleaning in a cleaning zone set along the travel route is complete, and a second condition that an amount of cleaning time that has elapsed after completion of previous maintenance exceeds a predetermined threshold value.

3. The cleaning system according to claim 2,
wherein the control device comprises a selection reception unit configured to receive a candidate condition to be applied which candidate condition is selected from among a plurality of preset candidate conditions including the first condition and the second condition, and
wherein the control device sets the candidate condition received by the selection reception unit as the maintenance condition.

4. The cleaning system according to claim 1,
wherein the control device comprises a zone setting reception unit configured to receive input of a zone along the travel route and receive a selection made from among a plurality of preset zones along the travel route, and
wherein the control device sets the zone received by the zone setting reception unit as a cleaning zone to be cleaned.

5. The cleaning system according to claim 1, wherein:
the at least one cleaning vehicle comprises a plurality of cleaning vehicles,
a plurality of the cleaning zones are set along the travel route, and
the control device associates a different cleaning vehicle with each of the cleaning zones, and causes each of the cleaning vehicles to perform the cleaning in the associated cleaning zone.

6. The cleaning system according to claim 1,
wherein the control device is configured to execute repetitive cleaning control that causes the cleaning vehicle to repeatedly perform the cleaning in the cleaning zone set along the travel route.
